(19) United States
(12) Patent Application Publication
(10) Pub. No.: US 2006/0198966 A1
(43) Pub. Date: Sep. 7, 2006

(54) Method for forming a silicon-containing film

(75) Inventors: Yuriko Kaino, Kanagawa (JP); Takahiro Kamei, Kanagawa (JP)

Correspondence Address: WOLF GREENFIELD & SACKS, PC, FEDERAL RESERVE PLAZA, 600 ATLANTIC AVENUE, BOSTON, MA, 02210-2206, US

(73) Assignee: Sony Corporation, Tokyo (JP)

(21) Appl. No.: 11/353,624

(22) Filed: Feb. 14, 2006

(30) Foreign Application Priority Data
Feb. 23, 2005 (JP) JP2005-046525
Nov. 2, 2005 (JP) JP2005-319098

(51) Int. Cl. C23C 14/28

(52) U.S. Cl. 427/595

(57) ABSTRACT

A method for forming a silicon-containing film on a surface of a substrate is described. In the method, a cyclopentasilane solution is filled in a cell to permit an inner wall surface of the cell and the cyclopentasilane solution to be in contact with each other. Subsequently, UV light is irradiated from a spot UV irradiator to cause the light to be irradiated on the cyclopentasilane solution in the vicinity of a region of an inner wall surface through a wall of the cell, thereby forming a silicon-containing film at the region. Thus, silicon-containing the film is formed without resorting to a thermal treatment by a reduced number of steps.

### CROSS REFERENCES TO RELATED APPLICATIONS

The present invention contains subject matter related to Japanese Patent Application JP 2005-319098 filed in the Japanese Patent Office on Nov. 2, 2005, the entire contents of which being incorporated herein by reference.

### BACKGROUND OF THE INVENTION

This invention relates to a method for forming a silicon-containing film and more particularly, to a method for forming a silicon-containing film by use of a silicon hydride-containing solution.

For the formation of an amorphous silicon film or a polysilicon film, there have been hitherto used a thermal chemical vapor deposition (CVD) method, a plasma CVD method, an optical CVD method, a vacuum deposition method, a sputtering method and the like. In general, a plasma-enhanced CVD method has been employed for the amorphous silicon film, (see Spear, W. E., “Solid State Com.”, 1975, Vol. 17, p. 1193), and a thermal CVD method has been widely used for the polysilicon film (see Kern, W., “Journal of Vacuum Science and Technology”, 1977, Vol. 14(5), p. 1082).

With the plasma-enhanced CVD method that has been frequently used for the formation of an amorphous silicon film, silane (SiH₄) or disilane (Si₂H₆) used as a starting gas is decomposed by glow discharge to permit a thin film of amorphous silicon to be grown on a substrate. For the substrate, crystalline silicon, glass, a heat-resistant plastic and the like are used, and the growth is possible usually at 400° C. or below. This method has a great advantage in that a film of a large area can be made at relatively low costs. With respect to the polysilicon film, the amorphous silicon film formed according to the above procedure is irradiated with a pulse oscillation excimer laser at intervals of about 25 ns to heat and melt the amorphous silicon film, followed by cooling the melted film to cause recrystallization, thereby forming a polysilicon film.

For the CVD method using a higher silicon hydride, several methods have been proposed including a method of thermally decomposing a higher silicon hydride gas at an atmospheric pressure or over (see Japanese Patent Publication No. Hei 5-469), a method of thermally decomposing a cyclic silicon hydride gas (see Japanese Patent Publication Hei 4-62703), a method using a branched silicon hydride gas (see Japanese Patent Laid-Open No. Sho 60-26665), a method where a higher silicon hydride gas including trisilane or higher silanes is subjected to thermal CVD at 480° C. or below (see Japanese Patent Publication No. Hei 5-56852) and the like.

Where a silicon film is formed according to the CVD method, however, a vapor phase reaction is used to cause particles to be formed in the vapor phase, with the attendant problem that the film-forming apparatus is deteriorated with the resulting lowering of device yield. Moreover, since the starting material is gaseous in nature, problems are involved in that it is difficult to obtain a film having a good step coverage on a substrate having irregular surfaces and a film-forming speed is low, with a throughput becoming low. Especially, the plasma-enhanced CVD method needs not only a complicated, expensive apparatus such as a high frequency generator, but also an expensive high vacuum device.

On the other hand, investigations have been made on the formation of a silicon film using, aside from such a CVD method as mentioned above, a coating method that does not need any expensive device. For an instance of such a method of forming a silicon film, a method of forming a silicon film has been reported in which a liquid silicon hydride is applied onto a substrate and heated, followed by subjecting to a thermal history including the temperature-rising step sufficient to permit a decomposition reaction to occur inside the applied film (see Japanese Patent No. 3517934). In addition, a method of forming a silicon film has been reported in which after UV irradiation of a solution containing cyclopentasilane, the solution is coated onto a support to form a coated film, followed by heating (see Japanese Patent No. 3424232).

### SUMMARY OF THE INVENTION

With the method of forming a silicon film as set out in the Japanese Patent No. 3517934, a polysilicon film is formed when a thermal history arriving at a temperature, for example, of 550° C. or over, has to be undergone. This temperature exceeds a heat-resistant temperature for almost all plastic materials and thus, a difficulty is involved in forming of a polysilicon film on a plastic substrate. Moreover, with the method of forming a silicon film as set forth in Japanese Patent No. 3424232, a silicon film is formed through thermal treatment, so that film formation on a plastic film is difficult. Further, when the silicon films formed by the above-indicated Japanese Patent Nos. 3517934 and 3424232 are patterned, a patterning step becomes necessary after the film formation step.

It is desirable to provide a method for forming a silicon-containing film by a reduced number of steps without resorting to a thermal treatment.

According to an embodiment of the invention contemplates to provide a method for forming a silicon-containing film on a surface of a substrate, which method including irradiating light on a solution containing a silicon-containing compound whose main chain is constituted of silicon in such a condition that the solution and the substrate are in contact with each other, so that the silicon-containing film is formed at a light irradiation region of a contact surface or face between the substrate and the solution.

According to such a method for forming a silicon-containing film as mentioned above, light is irradiated in a condition where the solution containing a silicon-containing compound and the substrate are in contact with each other, under which the mutual linkage or bond between silicon atoms and also between silicon atom and other atom in the silicon-containing film is broken and reunited or recombined to form a silicon-containing film. In this way, no heat treatment is necessary, but the silicon-containing film can be formed only by light irradiation. Thus, the formation procedure of the silicon-containing film can be simplified.

As stated hereinabove, according to the method of the invention for forming a silicon-containing film, the silicon-containing film can be formed without resorting to a thermal treatment. Thus, the silicon-containing film can be formed on a surface of a plastic substrate having a poor heat resistance. The silicon-containing film forming procedure is so simplified and thus, good productivity is ensured.

### BRIEF DESCRIPTION OF THE DRAWINGS

FIG. 1 is a schematic sectional view illustrating a method for forming a silicon film according to a first embodiment of the invention;

FIG. 2 is a graph showing transmittances of a quartz cell and a glass cell;

FIG. 3A is a schematic view illustrating a method for forming a silicon film according to a second embodiment of the invention and FIG. 3B is an enlarged view of an essential part of FIG. 3A;

FIG. 4 is a radiation spectrum chart of UV light from a spot UV irradiator used in Example 1 and Comparative Example 1;

FIG. 5 is an EDX spectrum chart of a deposition film obtained in Example 1;

FIG. 6 is an electron diffraction pattern of the deposition film obtained in Example 1;

FIG. 7A is a Raman spectrum chart of a deposition film obtained in Example 2 and FIG. 7B is a Raman spectrum chart for standard products of different types of silicon films; and

FIG. 8 is a UV spectrum chart of a deposition film obtained in Example 3.

### DETAILED DESCRIPTION OF THE PREFERRED EMBODIMENTS

The method for forming a silicon-containing film according to one embodiment of the invention is described in detail.

### First Embodiment

The silicon-containing compound used in the invention is one which has a main chain constituted of silicon atoms and also contains linkages between silicon atom and atoms other than silicon or substituents. The atoms linked or bonded to silicon include hydrogen, carbon, oxygen, nitrogen, sulfur, phosphorus, boron, a halogen and the like. The substituents bonded to silicon include those substituent containing such atoms as indicated above, i.e. a hydroxyl group, a carbonyl group, an ester group, an alkyl group, an alkenyl group, an alkoxy group, an aryl group, a heterocyclic group, a cyano group, a nitro group, an amino group, amido group, a thiol group and the like.

Such a silicon-containing compound as mentioned above is dissolved in a solvent described hereinafter. When light is irradiated in a condition where the solution and a substrate are in contact with each other, a silicon-containing film that is mainly composed of silicon linkages and additionally contains atoms other than silicon or substituents is formed at a light irradiated region of the contact surface of the substrate with the solution.

An instance of using a silicon hydride as the silicon-containing compound is illustrated below. For the silicon hydride, either a cyclic silicon hydride, or a linear or branched silicon hydride may be used. The cyclic silicon hydride contains not only a monocyclic silicon hydride, but also a ladder-structured cyclic silicon hydride wherein cyclic silicon hydrides are connected in such a way that two or more silicon atoms are shared and a cage-shaped cyclic silicon hydride wherein monocyclic structures of a silicon hydride are three-dimensionally connected with each other. Of these, a monocyclic silicon hydride represented by the chemical formula of SiₙH₂ₙ wherein n is an integer of 4 or over, or a linear or branched silicon hydride represent by the formula of SiₙH₂ₙ₊₂ wherein n is an integer of 3 or over is high in general versatility and is, in fact, preferred.

Specific examples of SiₙH₂ₙ include cyclotetrasilane (Si₄H₈), cyclopentasilane (Si₅H₁₀), cyclohexasilane (Si₆H₁₂), cycloheptasilane (Si₇H₁₄) and the like. Examples of SiₙH₂ₙ₊₂ include trisilane (Si₃H₈), normal tetrasilane (Si₄H₁₀), iso-tetrasilane (Si₄H₁₀) normal pentasilane (Si₅H₁₂), iso-pentasilane (Si₅H₁₂), neo-pentasilane (Si₅H₁₂), normal hexasilane (Si₆H₁₄), normal heptasilane (Si₇H₁₆), normal octasilane (Si₈H₁₈), normal nonasilane (Si₉H₂₀) and isomers thereof. For SiₙH₂ₙ₊₂, silylcyclopentasilane wherein a silyl group is bonded to cyclopentasilane may also be used. These silanes may be used singly or in admixture of plural silicon hydrides. In addition, these silanes may also be used in admixture of monosilane (SiH₄) and disilane (Si₂H₆) wherein n is less than 3. For illustration, single use of cyclopentasilane (Si₅H₁₀) of the following formula (1) is described hereinbelow

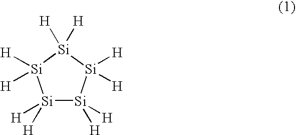

This cyclopentasilane may be used as it is after preparation thereof, or may be used after isolation thereof. For the preparation of cyclopentasilane, phenyldichlorosilane in tetrahydrofuran is cyclized, for example, with metallic lithium to provide decaphenylcycopentasilane, followed by treating with hydrogen chloride in the presence of aluminium chloride and further with lithium aluminium hydride and silica gel to prepare the cyclopentasilane.

Next, the thus obtained cyclopentasilane is dissolved in an appropriate solvent to obtain a silicon hydride solution. Such solvents are not limited to specific ones provided that they are able to dissolve cyclopentasilane and are not reactive with cyclopentasilane.

Preferred examples of the solvent include hydrocarbon solvents such as n-heptane, n-octane, decane, toluene, xylene, cymene, durene, indene, dipentaene, tetahydronaphthalene, decahydronaphthalene, cyclohexylbenzene and the like, ether solvents such as ethylene glycol dimethyl ether, ethylene glycol diethyl ether, ethylene glycol methyl ethyl ether, diethylene glycol dimethyl ether, diethylene glycol methyl ethyl ether, 1,2-dimethoxyethane, bis(2-methoxyethyl)ether, p-dioxane and the like, and aprotic polar solvents such as propylene carbonate, γ-butyllactone, n-methyl-2-pyrrolidone, dimethylformamide, dimethylsulfoxide, cyclohexanone and the like. These solvents may be used singly or in admixture of two or more. For illustration, toluene is used herein, for example, and cyclopentasilane is dissolved in toluene to prepare a cyclopentasilane solution.

The solution may contain, aside from the cyclopentasilane, a radical generator. Examples of the radical generator include biimidazole compounds, benzoin compounds, triazine compounds, acetophenone compounds, benzophenone compounds, α-diketone compounds, polynuclear quinone compounds, xanthone compounds, azo compounds and the like.

Next, the above-mentioned cyclopentasilane compound is brought into contact with a substrate on which a silicon film is to be formed. As shown in FIG. 1, for example, a cyclopentasilane solution 12 is filled in a cell 11 (substrate) made of quartz to cause an inner wall surface 11a of the cell 11 and the cyclopentasilane solution 12 to be contacted with each other. As will be described hereinafter, light is irradiated to form a silicon film 21 on the inner wall surface 11a. The filling of the cyclopentasilane solution 12 in the cell 11 is carried out in an atmosphere of an inert gas such as argon (Ar) or the like. After completion of the filling, the cell 11 is hermetically closed with a cap 13. This is to prevent oxygen from taking in the silicon film formed in a subsequent step.

It will be noted that although it has been stated above that although the material of the cell 11 (substrate), on which the silicon film 21 is formed, is made of quartz, the substrate material includes, aside from quartz, glass, plastics or the like. Especially, when a plastic material having a low heat resistance is used, a silicon film can be formed without resorting to a thermal treatment and such a plastic material can be favorably used in the practice of the invention. Nevertheless, if light is irradiated through the substrate as in this embodiment, the material of the substrate should preferably be high in transmittance of irradiated light.

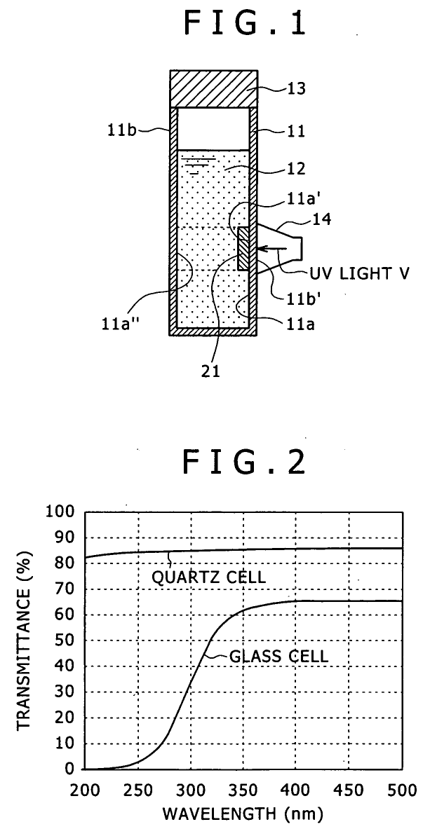

As will be described hereinafter, because light of 200 nm to 450 nm is transmitted in the practice of the invention, the substrate made of a material whose light transmittance is within such a wavelength range as indicated above is preferably used. For instance, as shown in FIG. 2, when a glass cell and a quartz cell are compared with each other, it is preferred to use a quartz cell that has a higher transmittance of light within a range of 200 nm to 450 nm. With plastics, a polyolefin film having a good transmittance of light within such a wavelength range as indicated above is preferred.

Next, as shown in FIG. 1, light is irradiated on the cell 11 filled with the cyclopentasialne solution 12. More particularly, light is irradiated at the cyclopentasilane solution 12 in the vicinity of the contact surface between the cell 11 and the cyclopentasilane solution 12. In this embodiment, a spot UV irradiator 14 is, for example, brought into intimate contact with a region 11b′ of an outer wall surface 11b of the cell 11, under which light is irradiated to permit the light to pass through the wall of the cell 11, thereby irradiating the cyclopentasilane solution 12 in the vicinity of a region 11a′ of an inner wall surface 11a that is an opposite side of the region 11b′. In this way, the linkage of the cyclopentasialne is broken and recombined to selectively form a silicon film 21 made of amorphous silicon or polysilicon at the region 11a′.

The light used in the practice of the invention should preferably have a wavelength range of from 200 nm to 450 nm that is fallen mainly within a UV wavelength range. More preferably, irradiation with both light within a wavelength of from 200 nm to 320 nm and light within a wavelength of 320 nm to 450 nm is used. Irradiation with two types of wavelengths of light enables one to reliably break and recombine the Si—Si bonds and Si—H bonds of cyclopentasilane and also to increase a formation speed of the silicon film 21.

In this embodiment, a mercury-xenon lamp is used, for example, as a light source of the UV irradiator 14, and a filter is used to allow UV light V having peak wavelengths in the vicinity of 290 nm, 325 nm and 365 nm to be emitted. It will be noted that although the wavelength range of irradiation light is appropriately changed depending on the type of silicon-containing compound, UV irradiation has high general versatility and, in fact, is preferred for the purposes of breaking and recombination of the bonds in the silicon-containing compound.

The light source of UV light V includes, aside from the mercury-xenon lamp, a low-pressure or high-pressure mercury lamp, a heavy hydrogen lamp, and discharge light sources of rare gases such as argon, krypton, xenon and the like, and also a YAG laser, an argon laser, a carbon dioxide laser, excimer lasers such as of XeF, XeCl, XeBr, KrF, KrCl, ArF, ArCl and the like may be used.

The irradiation energy from the UV light V is controlled depending on the output power of the UV irradiator 14 and the irradiation time. The change in the irradiation energy allows a thickness of the silicon film 21 to be set as desired.

Where the irradiation energy of the UV light V is satisfactorily high, the silicon film 21 is formed at the region 11a′ of the inner wall surface 11a as set out hereinabove and, at the same time, since the UV light V is irradiated on an opposing region 11a″ of the inner wall surface 11a in face-to-face relation therewith through the cyclopentasilane solution 12, a silicon film is also formed on that region 11a″. It is to be noted that the irradiation energy of the UV light V on the cyclopentasilane solution 12 in the vicinity of the opposing region 11a″ is lower than that of the UV light V irradiated on the cyclopentasilane solution 12 in the vicinity of the region 11a′, so that the silicon film formed at the opposing region 11a″ becomes thinner than the silicon film 21.

According to the method of forming a silicon film set forth hereinabove, the silicon film 21 can be formed without resorting to a thermal treatment and thus, the silicon film 21 can be formed on a surface of a substrate made of a plastic material of low heat resistance. Since the silicon film 21 can be formed only by irradiation of the UV light V, the formation procedure of the silicon film 21 is simplified, with good productivity.

Further, the silicon film is formable only at a light irradiation region, so that the position and shape of the light irradiation region are controlled to form a pattern of a silicon film at an arbitrary position in an arbitrary form. Thus, film formation and patterning can be carried out simultaneously.

It will be noted that although an instance of selectively forming the silicon film 21 at the region 11a′ of the inner wall surface 11a of the cell 11 has been illustrated in this embodiment, the formation of the silicon film 21 over a whole region of the inner wall surface 11a of the cell 11 is possible through irradiation of the UV light V throughout the outer wall surface 11b of the cell 11 at a portion thereof filled with the cyclopentasilane solution 12.

Moreover, this embodiment deals with an instance of forming the silicon film 21 only by irradiation of the UV light V, heating may be possible upon irradiation of the UV light V. Alternatively, UV light V may be initially irradiated to form a silicon film 21, followed by heating treatment.

### Embodiment 2

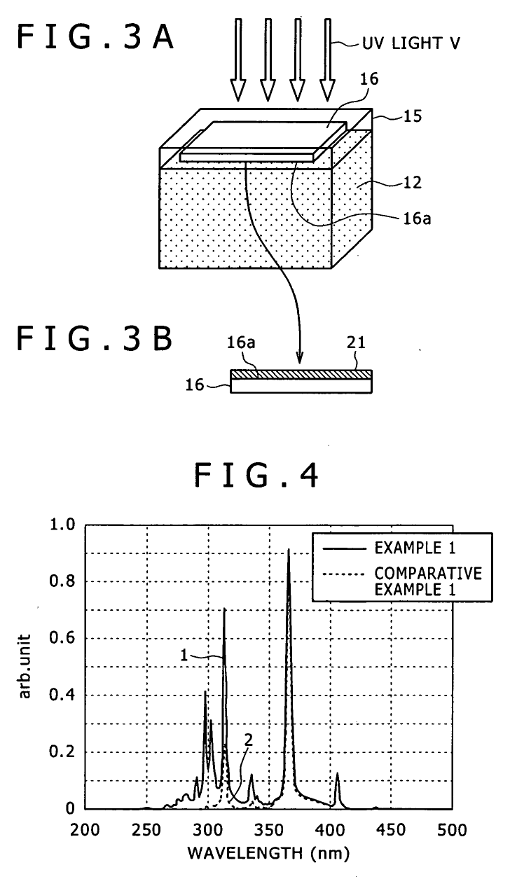

In this embodiment, an instance of forming a silicon film, for example, on a flat substrate is illustrated with reference to FIGS. 3A and 3B. It will be noted that a cyclopentasilane solution 12 as used in Embodiment 1 is employed as a solution containing a silicon hydride and like reference numerals indicate like parts or members in these figures.

As shown in FIG. 3A, a cyclopentasilane solution 12 is filled in a container 15. Next, a substrate 16 made, for example, of quartz is held in such a state that only a main surface side of the substrate 16 is immersed in or in contact with the cyclopentasilane solution 12. Subsequently, UV light V is irradiated toward a whole region of the substrate 16 from a side opposite to the contact surface 16a of the substrate 16 with the cyclopentasilane solution 12 to permit the cyclopentasilane solution 12 in the vicinity of the contact surface between the substrate 16 and the cyclopentasilane solution 12 to be irradiated through the substrate 16. It will be noted that the above procedure is carried out in an atmosphere of an inert gas such as Ar or the like.

In this way, as shown in the enlarged, sectional view of the essential part of FIG. 3B, a silicon film 21 made of amorphous silicon or polysilicon is formed over the whole region of the contact surface 16a of the substrate 16 with the cyclopentasilane solution 12.

It will be noted that although the UV light has been irradiated from a side opposite to the contact surface 16a between the substrate 16 and the cyclopentasilane solution 12, UV light V may be applied directly to the side of the contact surface 16a. In this case, the substrate 16 is so arranged that a surface on which the silicon film 21 is formed is turned upward at a bottom surface of the container 15 where the cyclopentasilane solution 12 has been filled. Next, the UV light V is irradiated toward the whole region of the substrate 16 from above. In this manner, the silicon film 21 is formed at the contact surface 16a between the substrate 16 and the cyclopentasilane solution 12.

Where UV light V is irradiated directly at the side of the contact surface 16a of the substrate 16 with the cyclopentasilane solution 12, UV light V may be irradiated from a side of a coated surface after coating of the cyclopentasilane solution 12 onto the surface of the substrate 16 by a method including, aside from such an immersion method as set out above, a spin coating method, a dip coating method, a spraying method and the like, for example.

It will be noted that although an instance of forming the silicon film 21 over a whole surface of the substrate 16 has been illustrated hereinabove, it is possible to form the silicon film in an arbitrary from at an arbitrary position by controlling the position and shape of a light irradiation region. In this case, light irradiation may be effected, for example, through a mask formed with a pattern therein to form a pattern of the silicon film 21 on the surface of the substrate 16. Alternatively, using a spot UV irradiator, the silicon film 21 may be descriptively subjected to pattern formation. In this way, the formation and patterning of the silicon film 21 can be performed by the same step.

According to the method of forming the silicon film 21 stated hereinabove, the silicon film 21 can be formed only by light irradiation without resorting to a thermal treatment, thus achieving a similar effect as in Embodiment 1.

The invention is described in more detail by way of examples, in which instances of forming a silicon film in a manner as set out in Embodiment 1 are described.

### EXAMPLE 1

As shown in FIG. 1, a toluene solution containing about 1.8 vol % of cyclopentasilane was filled in a 2 ml screw-capped quartz cell 11 in an atmosphere of Ar. Next, a spot UV irradiator 14 (LC-5 (attached with a 03-type filter), made by Hamamatsu Photonics K.K.) was brought into intimate contact with a region 11b′ of an outer wall surface 11b of the quartz cell 11 to irradiate light at an output of 3.6 W/cm². The irradiated light from the spot UV irradiator had, as shown in radiation spectrum 1 in the graph of FIG. 4, an irradiation wavelength range of 200 nm to 450 nm and had peaks at 290 nm and 305 nm within a wavelength range of 200 nm to 320 nm and a maximum peak at 365 nm within a wavelength range of 320 nm to 450 nm. The irradiation of the light over 3 minutes enabled one to observe a glossy deposition film at the region 11a′.

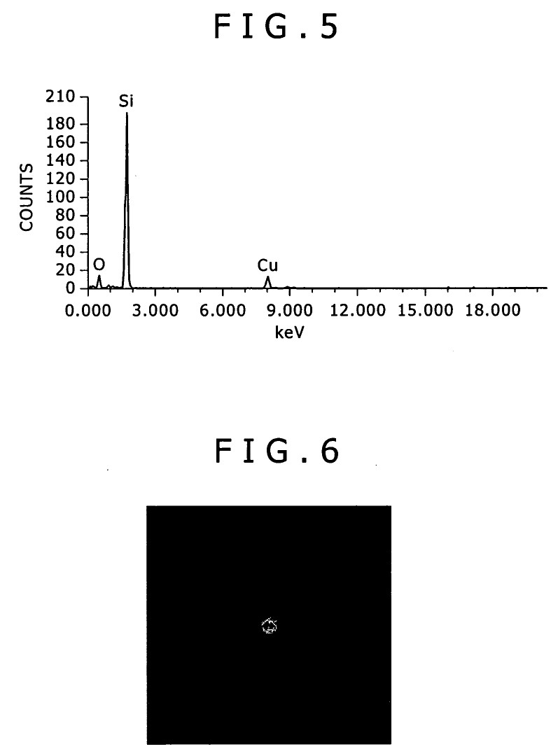

This deposition film was subjected to measurement of energy dispersion X-ray (EDX) spectroscopy, along with TEM image and electron diffraction image being confirmed. As a result, a significant Si peak is recognized as a component in the film in view of the EDX spectrum shown in FIG. 5. It should be noted that although a peak of oxygen is also detected in the spectrum, this oxygen is confirmed as being derived from the quartz cell. Moreover, it has been confirmed that in view of the TEM image, a uniform, dense deposition film is obtained and in view of the electron diffraction image shown in FIG. 6, the deposition film consists of an amorphous silicon film.

### EXAMPLE 2

As shown in FIG. 1, a toluene solution containing about 0.9 vol % of cyclopentasilane was filled in a 2 ml screw-capped quartz cell 11 in an atmosphere of Ar. Next, a spot UV irradiator 14 (LC-5 (attached with a 03-type filter), made by Hamamatsu Photonics K.K.) was brought into intimate contact with a region 11b′ of an outer wall surface 11b of the quartz cell 11, under which light of an irradiation wavelength range of 200 nm to 450 nm having a maximum peak at 365 nm was irradiated at an output of 3.6 W/cm² over five to six minutes. This permitted a glossy deposition film to be observed at the region 11a′.

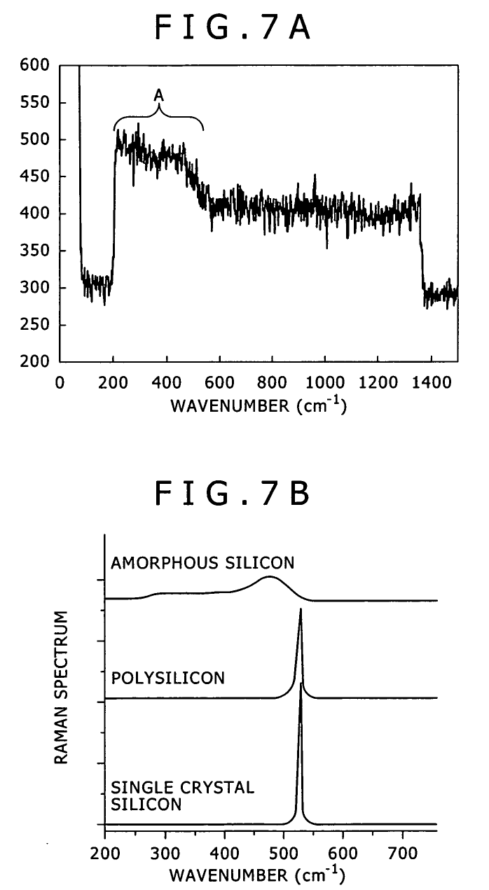

Reference is now made to FIGS. 7A and 7B wherein FIG. 7A shows a Raman spectrum of the deposition film and FIG. 7B shows Raman spectra for standard products of amorphous silicon, polysilicon and single crystal silicon. The comparison between the Raman spectrum of the deposition film in FIG. 7A and the respective Raman spectra in FIG. 7B reveals that a broad peak A inherent to amorphous silicon is seen in the graph of FIG. 7A. Although not particularly shown, the TEM image of the deposition film demonstrates the formation of an amorphous silicon film having a uniform thickness of approximately 100 nm.

### EXAMPLE 3

A cyclopentasilane/toluene solution having a concentration of cyclopentasialne different from that in Example 1 was filled in a 2 ml screw-capped quartz cell 11 in an atmosphere of argon. Next, UV light V was irradiated under the same conditions as in Example 1. In this way, a glossy deposition film was observed at a region 11a′ of an inner wall surface 11a of the cell 11 where irradiated with the UV light V.

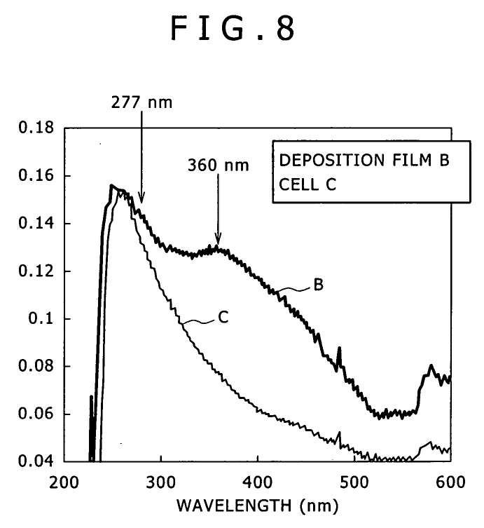

FIG. 8 shows UV spectrum B of the deposition film and UV spectrum C of the cell 11. As shown in FIG. 8, the UV spectrum B of the deposition film has peaks at 277 nm and 360 nm. These two peaks are inherent to crystalline silicon and it was confirmed that these peaks were located at similar positions as the peaks of a UV spectrum of a silicon wafer.

### EXAMPLE 4

A cyclopentasilane/toluene solution was filled in a 2 ml screw-capped glass cell 11 in an atmosphere of argon. This example differed from Example 1 in that the cell was made of glass. Next, light was irradiated under the same conditions as in Example 1. In the case, since the material of the cell 11 was glass and thus, transmittances were different from each other, so that the irradiation energy could be reduced by about 27%. In this example, a glossy deposition film was observed at a region 11a′ of an inner wall surface 11a of the cell 11 where irradiated with UV light V.

### COMPARATIVE EXAMPLE 1

For Comparative Example 1 relative to Examples 1 to 4, like Example 1, a cyclopentasilane/toluene solution was filled in a 2 ml screw-capped quartz cell 11 in an atmosphere of argon. Next, a spot UV irradiator 14 (LC-5 (attached with 05-type filter) made by Hamamatsu Photonics K.K.) having a filter of a type different from that of Example 1 was brought into intimate contact with a region 11b′ of an outer wall surface 11b of the quartz cell 11, under which light was irradiated at an output of 3.6 W/cm². The irradiated light from the spot UV irradiator had an irradiation wavelength range of 300 nm to 450 nm as is particularly shown in radiation spectrum 2 of FIG. 4 and had a maximum peak at 365 nm along with a peak at 325 nm. This light was irradiated over 10 minutes, but no deposition film was confirmed.

### COMPARATIVE EXAMPLE 2

For Comparative Example 2 relative to Examples 1 to 4, like Example 1, a cyclopentasilane/toluene solution was filled in a 2 ml screw-capped quartz cell 11 in an atmosphere of argon. Next, like Comparative Example 1, a spot UV irradiator 14 (LC-5 (attached with 03-type filter) made by Hamamatsu Photonics K.K.) was brought into intimate contact with a region 11b′ of an outer wall surface 11b of the quartz cell 11 through a band pass filer (365 nm), under which light as irradiated at an output of 3.6 W/cm². The light was irradiated over 20 minutes, but no deposition film was observed.

### COMPARATIVE EXAMPLE 3

For Comparative Example 3 relative to Examples 1 to 4, like Example 1, a cyclopentasilane/toluene solution was filled in a 2 ml screw-capped quartz cell 11 in an atmosphere of argon. Next, like Comparative Example 1, a spot UV irradiator 14 (LC-5 (attached with 03-type filter) made by Hamamatsu Photonics K.K.) was brought into intimate contact with a region 11b′ of an outer wall surface 11b of the quartz cell 11 through a band pass filter (291 nm), under which light was irradiated at an output of 3.6 W/cm². The light was irradiated over 20 minutes, but no deposition film was observed. In addition, after irradiation of the light over 40 minutes, a deposit was observed, but not in the form of a film.

While a preferred embodiment of the present invention has been described using specific terms, such description is for illustrative purposes only, and it is to be understood that changes and variations may be made without departing from the spirit or scope of the following claims.

1. A method for forming a silicon-containing film on a surface of a substrate, said method comprising irradiating light on a solution containing a silicon-containing compound whose main chain is comprised of silicon in such a condition that said solution and said substrate are in contact with each other, so that the silicon-containing film is formed at a light-irradiated region of a contact surface between said substrate and said solution.

2. The method for forming a silicon-containing film on a surface of a substrate according to claim 1, wherein said silicon-containing compound comprises a silicon hydride and said silicon-containing film comprises a silicon film.

3. The method for forming a silicon-containing film on a surface of a substrate according to claim 1, wherein said irradiating light has an irradiation wavelength within a range of 200 nm to 450 nm.

4. The method for forming a silicon-containing film on a surface of a substrate according to claim 1, wherein said solution is irradiated with light having a wavelength within a range of 200 nm to 320 and also with light having a wavelength within a range of 320 nm to 450 nm.

5. The method for forming a silicon-containing film on a surface of a substrate according to claim 1, wherein said solution is irradiated with light having wavelengths of 290 nm, 325 nm and 365 nm.

6. The method for forming a silicon-containing film on a surface of a substrate according to claim 1, wherein said light is irradiated from a side opposite to a contact face between said substrate and said solution through said substrate.

7. The method for forming a silicon-containing film on a surface of a substrate according to claim 1, wherein said silicon-containing film is subjected to patterning at an arbitrary position in an arbitrary form by arbitrarily controlling a position and shape of said light irradiation region.
